(19) United States
(12) Patent Application Publication
(10) Pub. No.: US 2012/0217617 A1
(43) Pub. Date: Aug. 30, 2012

(54) Semi-Polar Wurtzite Group III Nitride Based Semiconductor Layers and Semiconductor Components Based Thereon

(75) Inventors: Armin Dadgar, Berlin (DE); Alois Krost, Berlin (DE); Roghaiyeh Ravash, Magdeburg (DE)

(73) Assignee: Azzurro Semiconductors AG, Magdeburg (DE)

(21) Appl. No.: 13/496,957

(22) PCT Filed: Sep. 16, 2010
(86) PCT No.: PCT/DE2010/001094

§ 371 Date: May 15, 2012

(30) Foreign Application Priority Data
Sep. 20, 2009 (DE) 10 2009 042 349.4

(51) Int. Cl. H01L 29/38

(52) U.S. Cl. 257/615; 257/E29.105

(57) ABSTRACT

Semipolar wurtzite Group III nitride-based semiconductor layers and semiconductor components based thereon are described. Group III nitride layers have a broad range of applications in electronics and optoelectronics. Such layers are generally grown on substrates such as sapphire, SiC and, more recently, Si(111). The layers obtained are generally polar or have c-axis orientation in the direction of growth. For many applications in the field of optoelectronics, as well as acoustic applications in SAWs, the growth of non-polar or semipolar Group III nitride layers is interesting or necessary. The process according to the invention permits simple and inexpensive growth of polarisation-reduced Group III nitride layers without prior structuring of the substrate.

The invention relates to semipolar wurtzite Group III nitride-based semiconductor layers and semiconductor components based thereon.

Group III nitride layers generally grow in the polar c-axis orientation on substrates. For many applications, however, it is very interesting that GaN grows as a polarisation-reduced or as a nonpolar layer. In the case of light emitters, for example, a higher luminescence yield is then expected due to a reduction of the quantum-confined Stark effect, and in the case of SAW components, the excitation of a weakly coupling surface wave is permitted, which allows coating thicknesses, absorptions, etc. in liquids to be measured. Until now, it has only been possible to grow such layers on r- or m-planar sapphire and hexagonal SiC substrates tilted from the c-axis, i.e. on a-planar or m-planar SiC substrates. On silicon, which is inexpensive and easier to process industrially, growth of c-planar GaN is almost always dominant. The growth of highly textured r-planar GaN on Si (001) using a special form of process control has been shown (F. Schulte, J. Bläsing, A. Dadgar, and A. Krost, Appl. Phys. Lett. 84, 4747 (2004)), but only with a surface that is unsuitable for applications due to the occurrence of four equally preferred alignments. It has also been shown that polarisation-reduced GaN can be obtained on structured silicon by appropriate pre-treatment of the substrate surface, e.g. by masking, etching, etc. (see, for example, M. Yang, H. S. Ahn, T. Tanikawa, Y. Honda, M. Yamaguchi, N. Sawaki, J. Cryst. Growth 311, 2914 (2009) or T. Tanikawa, D. Ruolph, T. Hikosada, Y. Honda, M. Yamaguchi, N. Sawaki, J. Cryst. Growth 310, 4999 (2009)).

Obtaining a planar polarisation-reduced layer directly on silicon substrates without complex structuring has not been achieved until now. One reason for this is that on most semiconductor surfaces of zinc blende or diamond lattice materials, a nucleation layer grown at high temperatures results in a c-axis orientation.

In theory, a polarisation-reduced orientation of the Group III nitride layer can be achieved by using a surface which is misoriented by more than 9° to the (111) surface, on a planar substrate with a zinc blende or diamond lattice structure, as stated in claim 1. In the case of silicon, for example, such surfaces mostly consist of a series of stable (111) surfaces alternating with (001)-type steps or surfaces. With suitable process control, GaN now grows with c-planar orientation on (111) surfaces and is therefore inclined by the respective angle in relation to the surface. This is achieved particularly well at a weak inclination, as for example with Si(211), because the (111) surface terraces are then several atoms wide. If the Group III nitride layer is to be tilted to significantly larger angles relative to the surface, a substrate should be used in which the (111) planes are tilted as much as possible relative to the surface normal. These are planes such as Si(311), Si(411), Si(511) etc., where it is recommended, as described in claim 8, that the substrate be pre-treated, i.e. that wide steps with (111) surfaces be created by treatment in physical or chemical processes in which the resultant (111) terraces have a threefold surface symmetry. Appropriate pre-treatment allows higher steps and therefore wider (111) planes on which the Group III nitride layer then grows almost exclusively with c-axis orientation. In order to prevent contamination, the substrate is ideally baked in an ultrapure chamber prior to epitaxy, thus forcing the clustering of steps and the formation of wider (111) terraces.

Growth is ideally on Group IV semiconductor surfaces, as described in claim 5, although zinc blende materials such as GaAs, GaP or InP are also well suited. This is ultimately related to the growth parameters being applied. For example, it is not possible to grow a MOVPE GaN layer on germanium at normal temperatures (1050° C.) because the melting point is less than 1000° C. However, such a substrate is very suitable for epitaxy at lower temperatures, be it by MOVPE or, even better, by MBE. The above observations also apply to growth on germanium at low temperatures. Surfaces with (211), (311) and (322) orientation are ideally suitable for growth, as described in claims 2-4. Silicon surfaces such as Si(211), (311) and (322), especially, as well as any other silicon surfaces having a high proportion of Si(111) terraces, are suitable in this regard. What are important, as described in claim 9, are terraces having wide steps with (111) surfaces, the resultant (111) terraces having a width that is at least that of two monolayers, i.e. these terraces are not mere step edges, but have at least three adjacent surface atoms in one plane, with the result that the threefold symmetry of such surfaces is recognisable. Surfaces with higher indexes, such as (411) and (511) surfaces, are also suitable, however, depending on growth temperature and pre-treatment, since it is possible for wider (111) surface sections to be formed in these cases also, and thus for suitable seeding conditions to be provided. It has been found, however, that growth becomes more difficult the greater the angle of inclination, since the crystallites twist and tilt more towards each other due to the more poorly oriented seeding of the crystallites and/or the increasing density of well-oriented seeds.

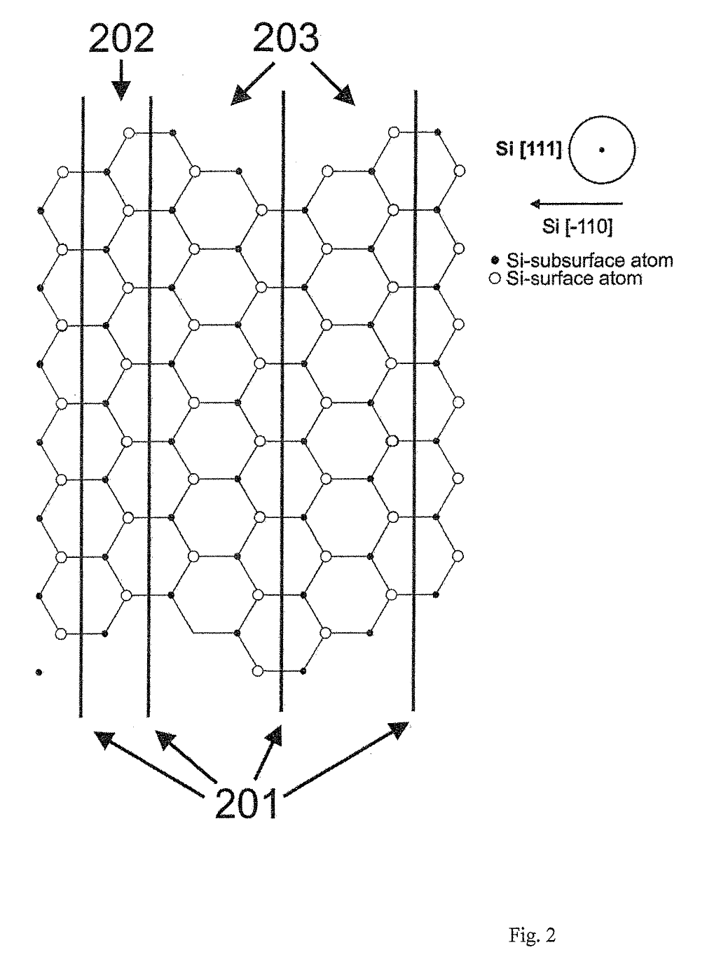

FIG. 2 shows a schematic view of a possible surface arrangement. Possible steps (201) can be seen, and between them the terraces of the (111) surfaces, which exhibit either zero symmetry (202) or threefold symmetry (203) of the surface atoms. This means that, depending on the material, the steps should be at least three nm wide or, according to claim 9, two monolayers wide.

Without this arrangement, growth of the Group III nitride layer is not monocrystalline, or is not textured in one alignment, which is essential for a closed layer of high quality.

In order that nucleation leads to monocrystalline growth, it is advantageous to grow a nucleation layer at a temperature or temperatures below 900° C. in the case of gas-phase methods and below 700° C. in the case of molecular beam and sputter methods, as described in claim 6. The nucleation layer therefore grows at a significantly lower temperature than the normal growth temperatures for GaN and AlN, which are higher than 1000° C. in methods such as MOVPE and HVPE. Temperatures around 700° C. are ideal. In methods that work at lower temperatures, in contrast, a significant reduction in the temperature of the nucleation layer is not imperative. By applying this kind of nucleation at low temperatures, nucleation permitting monocrystalline growth is achieved on (111) surfaces only. On all other crystal orientations, nucleation tends to be significantly more polycrystalline. As a result, the seeds that do not have a c-axis orientation grow more slowly on these other surfaces and can be dominated by the well-oriented crystallites grown on the (111) surfaces, thus resulting in a monocrystalline layer.

For processes which operate at temperatures significantly higher than 900° C., it is also advantageous for the growth of GaN when the nucleation layer contains a high percentage of aluminium, i.e. consists of AlN, AlGaN, AlInN or AlGaInN—as described in claim 7. This prevents any meltback etching reaction that destroys the layer and the substrate.

With said production process, many kinds of components can be manufactured in which polarisation reduction has advantageous effects. These components include light-emitting diodes, transistors, MEMS and SAW-based filters and sensors.

A short description will now be provided of the production process for the buffer layer that is required for subsequent components.

Layer growth generally begins, preferably, with pre-treatment of the substrate surface in order to clean the latter of any organic residues and to free it of any oxides. This is done using a wet chemical method or baking method, the latter preferably being carried out in an ultrapure chamber, in the case of a Group IV substrate, in order to prevent any unwanted contamination of the surface. Wet chemical methods are frequently based on targeted oxidation of the surface, for example with H₂SO₄, and subsequent removal of the oxide by HF.

It is possible in this way to obtain a hydrogen-terminated surface with which the desired formation of steps is made possible in the first place, since oxidised surfaces do not generally have any desired crystalline arrangement. The substrate pre-treated in this manner is then placed in the reactor chamber and for subsequent nucleation is brought as rapidly as possible to the nucleation temperature. The growth of the nucleation layer preferably begins by pre-depositing the Group III element to achieve coverage of about one monolayer. This prevents any undesired nitridation of the substrate surface. Precise execution of this step is dependent on the layer production process and the reactor geometry. It is crucial that nucleation is carried out in such a way that the surface atoms of the substrate do not lose their regular arrangement due to uncontrolled nitridation, which may subsequently result in increased polycrystalline growth. Dosing the nitrogen precursor into the stream then leads to nitridation of the Group III surface atoms that are usually applied shortly before, and to growth of the nucleation layer, which is typically between 10 and −50 nm thick. This is followed by a pause in growth, during which the surface is stabilised with the nitrogen precursor, the temperature is set to the growth temperature necessary for thicker, high-quality layers and a component buffer layer is grown. The active or functional layers of the component are then grown.

To obtain polarisation-reduced layers with larger tilt angles of the c-axis, it is necessary to use substrates that by nature have only a small proportion of (111) surfaces. In such cases, it is advantageous to achieve stronger step bunching and hence broader terraces on the surface by treating the substrate. This is mostly achieved with tempering processes in which the substrate is baked in a suitable carrier gas stream (H₂ or N₂), as a result of which the surface is modified. Depending on the type of substrate, the surface must be stabilised during such a process in order to prevent any degradation, e.g. stabilising GaAs growth with arsenic, or InP and GaP growth with phosphorus. In the case of silicon, in MOVPE processes at least, care must be taken to ensure that no desorption of deposits in the reactor vessel occurs as a result of heating. This is easily done in the case of some reactor types whose interior parts covered with deposits from previous experiments are replaced, whereas it is necessary in the case of other reactor types to monitor not only the temperature but also the duration of the step being performed. MBE is advantageous here, or an additional chamber for pre-treatment that is connected to the MOVPE reactor and ideally permits transfer of the substrate while it is still hot.

When growing layers on a surface of a III-V substrate with zinc blende structure, misoriented by more than 9° to the (111) surface, nitridation of at least one monolayer of the substrate surface can be carried out by passing ammonia, a nitrogen-releasing compound or nitrogen radicals over the surface before Group III nitride growth commences, as described in claim 10. When growing the nucleation layer on III-V zinc blende substrates such as GaAs, it is therefore possible to convert the substrate by nitridation of the upper substrate layers, i.e. to GaN in the case of GaAs. Such processes are generally started by injecting ammonia or nitrogen radicals at temperatures exceeding 350° C. After achieving a sufficiently protective Group III nitride layer, the temperature is usually increased further to the optimal temperature for Group III nitride growth, and growth of the component layer is started. It is even possible with this method to achieve monocrystalline growth without wide (111) terraces being required. The process can also be started with initial stabilization of the III-V-semiconductor layer with the Group V element, i.e. with an As precursor in the case of GaAs, for example, and then converting the precursor by adding the nitrogen source. This approach also allows a higher temperature for conversion, in that vaporisation of the Group V component before the nitrogen source is switched on can be prevented.

Growth on silicon substrates in a MOVPE process shall now be described. After cleaning, the substrate is placed in the reactor or coating chamber and heated to approximately 680° C., ideally in a hydrogen atmosphere. Due to the hydrogen atmosphere, it is possible to stabilise a prepared hydrogen-terminated surface, which is advantageous for nucleation. The first step, lasting approximately 2-15 seconds, involves feeding an initial stream of aluminium in the form of an aluminium precursor such as trimethyl aluminium. That step is followed by opening the oxygen precursor, such as ammonia, or for example dimethyl hydrazine, which is very suitable at low temperatures. The aluminium feed ideally remains simultaneously open. The ammonia causes nitridation of the previously deposited Al to form AlN, and in the further course of the process a partially ordered but partially unordered AlN layer grows. Regions with a high proportion of (001) steps generally exhibit greater disarray of crystallites compared to (111)-type surfaces.

It has been discovered that it is advantageous to maintain a high feed rate of the Al precursor, such as trimethyl aluminium, i.e. a relatively high growth rate for the tilted orientation of crystallites that is desired. However, the ideal parameters are dependent on the type of reactor and must be determined by optimising parameters in typical engineering fashion.

As a result of this initial, imperfectly ordered nucleation, it is possible during subsequent growth, for example of a GaN layer at temperatures around 1050° C., that undesired orientations are also grown. However, growth is clearly dominated by ordered crystallites, in that they grow faster and therefore outgrow the disordered crystallites. The thickness of the highly disordered layer thus obtained is mostly around 30 nm, rarely 100 nm or more. It is not until crystallites with the preferred orientation are preferentially grown that growth of a smooth, closed and monocrystalline layer is made possible. In the case of growth on silicon in the MOVPE process, and also in other processes that operate at similar temperatures, the possible reaction of gallium with the silicon at high temperatures often results in “meltback etching”, which destroys the layer. This can basically be prevented by an AlN nucleation layer, such as the one that is also used here. However, the ideal nucleation layer for the process being described here is not fully closed, due to the low thickness of only about 10 nm, and the presence of polycrystalline growth. In order to prevent any reaction of Ga and Si, which would not occur until later in the growth process, it is recommended that a protective Al-containing layer, such as AlGaN, be grown at normal growth temperature in the MOVPE process, i.e. above 950° C., which generally grows with a thickness between 30 and 300 nm in such a closed manner that the substrate is sufficiently protected. Aluminium concentrations of around 15% in that layer are sufficient to produce this protecting effect. In the case of MBE growth, in contrast, it is basically possible to apply GaN directly to the substrate and to do without an AlGaN layer. In order to prevent cracking during cooling, as a result of thermal mismatching of layer and substrate, it is advantageous at layer thicknesses of around 1 μm and more, either to introduce a pre-stressed AlGaN layer into the lower buffer or to use low-temperature AlN interlayers. Due to the initially poor quality of material and the fact that the a closed layer is not obtained until some hundreds of nanometres have grown, the use of AlGaN buffers for compressive pre-stressing of the GaN layer, often described in the literature, is not very efficient. Using LT AlN layers is more efficient in this case. Due to the lower coefficient of thermal expansion perpendicular to the c-axis of the Group III nitride layer, the tendency for cracking to occur decreases with increasing tilt angle, i.e. it is also possible to obtain layer thicknesses of more than 1 μm that are free of cracks, without using layers that reduce stress.

A brief description of the Figures shall now be provided.

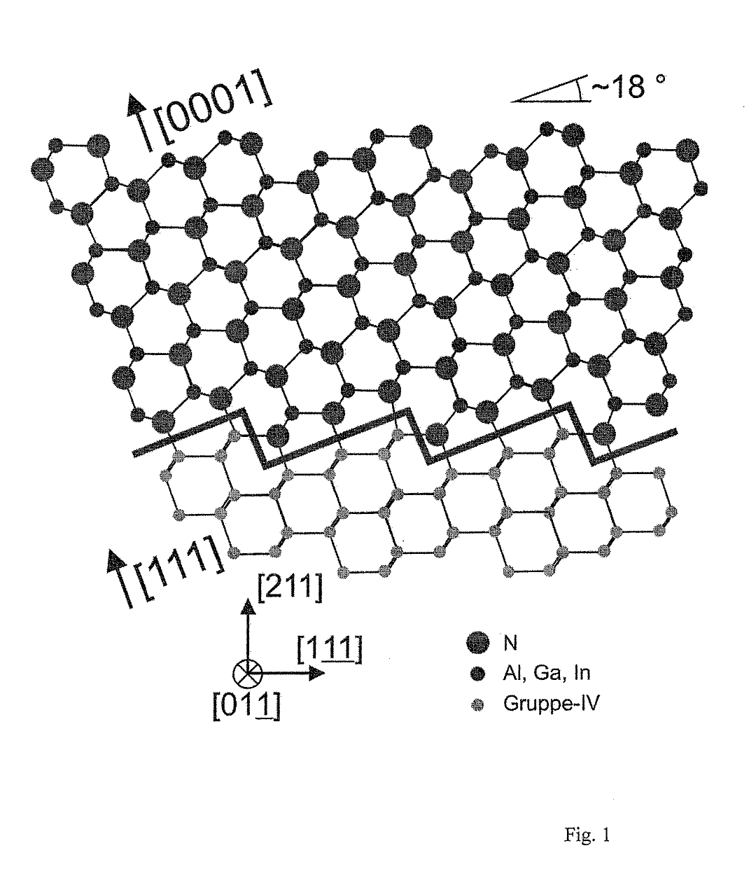

FIG. 1 shows, in a cross-sectional view, an example of a possible boundary interface between a Group III nitride layer and a Group IV substrate having a (211) surface. Said surface consists of (111) terraces and (001) steps. The (111) terraces are tilted approximately 18° relative to the surface normal plane. Due to the perpendicular growth of a c-axis orientation Group III nitride layer on this (111) surface, the Group III nitride layer grows at a tilt of approximately 18° to the surface normal plane of the substrate, which corresponds approximately to a (1016) surface.

FIG. 2 shows a schematic view of a tilted (111) surface, although only the (111) segments can be seen. Terraces with (111) surfaces and which are either only one monolayer wide (202) or wider (203) can form between the steps (201). No threefold symmetry of the surface atoms can be identified on the narrow terrace (202); such symmetry is found on the wider terraces (203) only. However, these are absolutely essential for growing a high-quality layer, because only then is it possible for the Group III nitride layer to have sufficient orientation on the substrate.

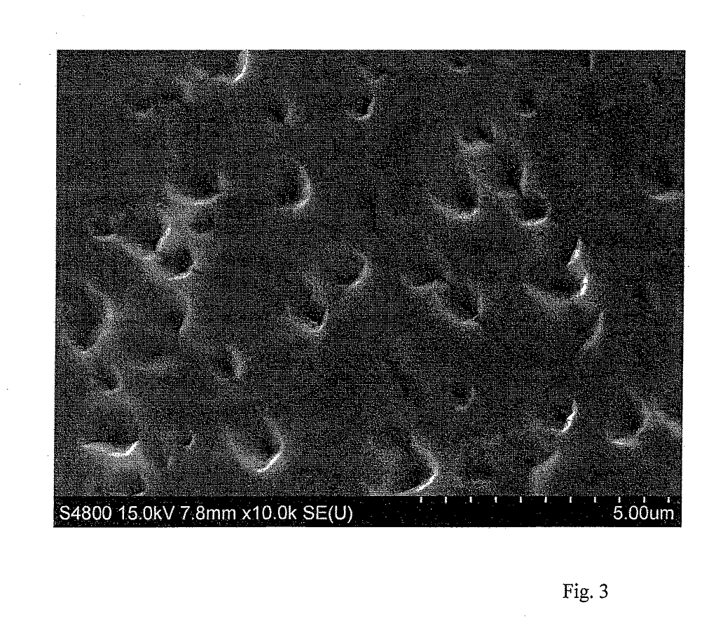

FIG. 3 shows a scanning electron microscope picture of a GaN layer grown on a Si(211) surface. The craters that are still present can be eliminated by optimising the growth process.

The invention relates to all Group III nitrides on zinc blende or Group IV substrates with an orientation deviating by more than 9° from the (111) surface, and which may still have (111) surfaces or (111) steps. The designations used for the surfaces or directions—( ) for surfaces and [ ] for directions—are intended to include all equivalent surfaces and directions, such as the (111), (111), (111), (111), (111), (111), (111) surfaces in the case of (111). The invention also relates to all epitaxial production processes that are suitable for producing Group III nitride layers. It is generally necessary in that regard to adjust the growth temperatures and V-III ratios to the specific circumstances in which the method is being applied. For example, the growth temperatures in MBE are usually some hundreds of degrees lower than those in the MOVPE or HVPE methods.

Tilting by more than 9° from the (111) surface normal plane, as described in claim 1, is upwardly limited, by nature, to surfaces that are tilted less than 7° from the (110) or (001) surface. For these orientations, monocrystalline c-axis orientation growth is described for the Si case in the literature, so tilted growth is not possible in any meaningful sense because the small tilting angle that is possible would not result in any significant degree of polarisation reduction. It is essential for the growth of semipolar component layers that tilting away from the (111) surface is such that the formation of (111)-type surfaces is still possible.

### Abbreviations:

FET: Field-effect transistor
HVPE: Hydride vapour phase epitaxy, hydride gas phase epitaxy
MBE: Molecular beam epitaxy
MEMS: Micro-electro-mechanical systems
MOVPE, MOCVD: Metal organic vapour phase epitaxy
SAW: Surface acoustic wave

What is claimed is:

1. Semipolar wurtzite Group III nitride-based semiconductor layers,
characterised by
growth on a planar substrate with a zinc blende or diamond lattice structure and a surface misoriented by more than 9° to the (111) surface.

2. The semipolar wurtzite group-III nitride-based semiconductor layers according to claim 1,
characterised by
growth on (211) surfaces.

3. The semipolar wurtzite group-III nitride-based semiconductor layers according to claim 1,
characterised by
growth on (311) surfaces.

4. The semipolar wurtzite group-III nitride-based semiconductor layers according to claim 1,
characterised by
growth on (322) surfaces.

5. The semipolar wurtzite group-III nitride-based semiconductor layers according to claim 1,
characterised by
growth on Group IV semiconductor surfaces.

6. The semipolar wurtzite group-III nitride-based semiconductor layers according to claim 1,
characterised by
growth of a nucleation layer at a temperature or temperatures below 900° C. in the case of gas-phase methods and below 700° C. in the case of molecular beam and sputter methods.

7. The semipolar wurtzite group-III nitride-based semiconductor layers according to claim 1,
characterised by
growth of a nucleation layer containing Al.

8. The semipolar wurtzite group-III nitride-based semiconductor layers according to claim 1,
characterised by
the creation of wide steps with (111) surfaces by treatment in physical or chemical processes in which the resultant (111) terraces have threefold surface symmetry.

9. The semipolar wurtzite group-III nitride-based semiconductor layers according to claim 1,
characterised by
the creation of wide steps with (111) surfaces, the resultant (111) terraces having a width that is at least that of two monolayers.

10. The semipolar wurtzite group-III nitride-based semiconductor layers according to claim 1,
characterised by
growth on a surface of a III-V substrate with zinc blende structure, misoriented by more than 9° to the (111) surface, and nitridation of at least one monolayer of the substrate surface by passing ammonia, a nitrogen-releasing compound or nitrogen radicals over the surface before Group III nitride growth commences.

11. Semiconductor components
characterised in that
they are based on semiconductor layers according to claim 1.
